(19) United States
(12) Patent Application Publication
(10) Pub. No.: US 2014/0216339 A1
(43) Pub. Date: Aug. 7, 2014

(54) RAW MATERIAL VAPORIZING AND SUPPLYING APPARATUS

(71) Applicant: FUJIKIN INCORPORATED, Osaka (JP)

(72) Inventors: Masaaki Nagase, Osaka (JP); Atsushi Hidaka, Osaka (JP); Kaoru Hirata, Osaka (JP); Ryousuke Dohi, Osaka (JP); Kouji Nishino, Osaka (JP); Nobukazu Ikeda, Osaka (JP)

(73) Assignee: FUJIKIN INCORPORATED, Osaka (JP)

(21) Appl. No.: 14/170,953

(22) Filed: Feb. 3, 2014

Related U.S. Application Data
(63) Continuation-in-part of application No. PCT/JP2012/003783, filed on Jun. 11, 2012.

(30) Foreign Application Priority Data
Aug. 1, 2011 (JP) 2011-167915

(51) Int. Cl. C23C 16/448

(52) U.S. Cl. CPC C23C 16/4485
USPC 118/712; 118/726

(57) ABSTRACT

A raw material vaporizing and supplying apparatus including a source tank in which a raw material is stored, a raw material gas supply channel through which raw material gas is supplied from an internal space portion of the source tank to a process chamber, a pressure type flow rate control system which is installed along the way of the supply channel, and controls a flow rate of the raw material gas which is supplied to the process chamber, and a constant temperature heating unit that heats the source tank, the supply channel, and the pressure type flow rate control system to a set temperature, wherein the raw material gas generated in an internal space portion of the source tank is supplied to the process chamber while the pressure type flow rate control system performs flow rate control.

This is Continuation-in-Part Application in the United States of International Patent Application No. PCT/JP2012/003783 filed Jun. 11, 2012, which claims priority on Japanese Patent Application No. 2011-167915, filed Aug. 1, 2011. The entire disclosures of the above patent applications are hereby incorporated by reference.

### BACKGROUND OF THE INVENTION

1. Technical Field

The present invention relates to an improvement in a raw material vaporizing and supplying apparatus of semiconductor manufacturing equipment using so-called metalorganic chemical vapor deposition (hereinafter called MOCVD), and more particularly, relates to a raw material vaporizing and supplying apparatus which is capable of supplying raw material gas while highly accurately performing flow rate control of even a liquid or solid raw material at a low gas pressure, to a set flow rate, and which makes it possible to significantly simplify and downsize the apparatus structure.

2. Description of the Related Art

Conventionally, as a raw material vaporizing and supplying apparatus for semiconductor manufacturing equipment, many apparatuses using a bubbling method or a direct vaporization method have been utilized. In contrast thereto, a raw material vaporizing and supplying apparatus using a baking method in which raw material gas is generated by warming, and the saturated gas is supplied to a location using raw material, has a host of problems in regards to stability in generation of raw material gas, control of gas quantity and gas pressure of the raw material gas, flow rate control of the raw material gas(raw material gas or steam), and the like. Therefore, the development and utilization of such a device have been relatively less than apparatuses using other methods.

However, because a raw material vaporizing and supplying apparatus using a baking method is configured to supply raw material gas (raw material gas or steam) at a saturated gas pressure generated from a raw material, directly to a process chamber, various disadvantages are avoided that are caused by a fluctuation in concentration of a raw material gas in process gas, such as are presentin a raw material vaporizing and supplying apparatus using a bubbling method. The baking method thus has high utility for keeping and improving the quality of semiconductor products.

FIG. 15 shows an example of the raw material vaporizing and supplying apparatus using a baking method, that is configured such that a metal-organic compound 36, stored in a cylinder container 30, is warmed to a constant temperature inside an air constant temperature room 34, and raw material gas (raw material gas or steam) G₀ generated in the cylinder container 30 is supplied to a process chamber 37 through a gateway valve 31, a mass flow controller 32, and a valve 33.

In addition, in FIG. 15, reference numeral 38 denotes a heater, reference numeral 39 denotes a heater, and reference numeral 40 denotes a vacuum exhaust pump. Further, reference numeral 35 denotes contant constant air temperature room in which a raw material gas supply system composed of the gateway valve 31, the mass flow controller 32, the valve 33, and the like is warmed, which is for preventing condensation of the raw material gas G₀.

That is, in the raw material vaporizing and supplying apparatus of FIG. 15, first, by heating the cylinder container 30, the metal-organic compound 36 is evaporated, which raises the gas pressure in the internal space of the container. Next, by opening the gateway valve 31 and the valve 33, the generated raw material gas (raw material gas or steam) G₀ is supplied to the process chamber 37 while being controlled to have a set flow rate by the mass flow controller 32.

For example, where the metal-organic compound 36 is trimethylindium (TMIn), the cylinder container 30 is heated to about 80° C. to 90° C.

Furthermore, the raw material gas supply system composed of the mass flow controller 32, the gateway valve 31, the valve 33, and the like are heated to about 90° C. to 100° C. in the constant air temperature room 35, which prevents the raw material gas G₀ from condensing inside the mass flow controller 32 and the like.

Because the raw material vaporizing and supplying apparatus of FIG. 15 supplies the raw material gas G₀ directly to the process chamber 37, it is possible to precisely feed a desired quantity of a raw material to the process chamber 37 by highly accurately performing flow rate control of the raw material gas G₀.

However, there remain many unsolved problems in the raw material vaporizing and supplying apparatus shown in FIG. 15 as well. The first problem regards the accuracy of flow rate control and stability of flow rate control of the raw material gas G₀ to be supplied to the process chamber 37.

That is, the raw material vaporizing and supplying apparatus of FIG. 15 is configured to control a supply flow rate of the raw material gas G₀ by use of the mass flow controller (a thermal type mass flow rate control system) 32, and heat the mass flow controller 32 to 90° C. to 100° C. inside the air constant temperature room 35, thereby preventing condensation of the raw material gas G₀.

On the other hand, as is well known, in the mass flow controller 32, in general, as shown in FIG. 16, a gas flow of a smaller quantity than a flow rate of a bypass group 32d is made to circulate through an ultrafine sensor pipe 32e at a constant rate.

Furthermore, a pair of resistance wires R1 and R4 for control, which are connected in series, are wound around this sensor pipe 32e, and a sensor circuit 32b connected thereto outputs a flow rate signal 32c showing a monitored mass flow rate value.

Further, FIG. 16 shows a basic structure of the above-described sensor circuit 32b. A series-connected circuit of two standard resistances R2 and R3 is connected in parallel to the series connection of the resistance wires R1 and R4, to form a bridge circuit. A constant current source is connected to this bridge circuit, and further, a differential circuit whose input side is connected to a connection point between the resistance wires R1 and R4 and a connection point between the standard resistances R2 and R3 is provided, to find a difference in electrical potentials of the both connection points, so as to output this difference in the electrical potentials as the flow rate signal 32c.

Here, assuming that the gas G₀′ (divided from the raw material gas) flows in the sensor pipe 32e at a mass flow rate Q, this gas G₀′ is warmed by heat generation of the resistance wire R1 located on the upstream side, and flows to a position on which the resistance wire R4 is wound around on the downstream side. As a result, a transfer of heat is caused, to cool down the resistance wire R1, and heat the resistance wire R4. Thus, a difference in temperature, i.e., a difference in resistance values is generated between the both resistance wires R1 and R4, and a difference in the electrical potentials generated at this time is substantially proportional to a mass flow rate of the gas. Accordingly, it is possible to find a mass flow rate of the gas G₀′ flowing at that time by multiplying this flow rate signal 32c by a predetermined gain.

As described above, in the mass flow controller 32, first, heat of the portion of the resistance R1 is removed by the gas fluid G₀′ made to separately flow into the sensor pipe 32e, and as a result, the resistance value of the resistance R1 drops, and a quantity of heat of the gas fluid G₀′ flowing into the portion of the resistance R2 is increased, which raises a temperature of the resistance R4 to increase its resistance value, so as to generate a difference in electric potentials in the bridge, thereby measuring a mass flow rate of the raw material gas G_{o.}

Therefore, it is unavoidable to cause a temperature fluctuation in the gas G₀′ flowing in the ultrafine sensor pipe 32e. As a result, a temperature distribution in the vicinity of the sensor pipe 32e of the mass flow sensor 32 becomes uneven, and therefore, the raw material gas G₀₄ is, such as TMGa (trimethylgallium), liquid (whose freezing point is −15.8° C., and boiling point is 56.0° C.) at room temperature and spontaneously combusts due to contact with air. In the case of a gas flow of a metal-organic material having the physical property that a fluctuation in a saturated gas pressure by temperature is large (35 kPa abs./30° C., 120 kPa abs./60° C.), not only a reduction in accuracy of flow rate control, but also liquescence of the gas G₀′ in the portion of the sensor pipe 32e, clogging of the gas G₀′ thereby are easily caused, which poses a problem for stable supply of the raw material gas G₀.

The second problem regards the increase in size of raw material vaporizing and supplying apparatuses. The conventional raw material vaporizing and supplying apparatus of FIG. 15 is configured such that the cylinder container 30 and the mass flow controller 32, and the like are installed as separate bodies, and the cylinder container 30 and the mass flow controller 32 are respectively disposed inside different constant air temperature rooms 34 and 35.

As a result, the problem is that the installation spaces for the respective members composing the raw material vaporizing and supplying apparatus are relatively increased, which makes it impossible to significantly downsize the raw material vaporizing and supplying apparatus.

### CITATION LIST

### Patent Document

Patent Document 1: Japanese Published Unexamined Patent Application No. Hei 2-255595

Patent Document 2: Japanese Published Unexamined Patent Application No. 2006-38832

### SUMMARY OF THE INVENTION

### Problems to be Solved by the Invention

It is a main object of the present invention to solve the problems described above in the conventional raw material vaporizing and supplying apparatus using a baking method. That is, the problems (A) and (B). Problem (A) arises because the flow rate control of raw material gas (raw material gas or steam) is performed by use of a thermal type mass flow rate control system (mass flow controller), a temperature fluctuation in the gas G₀′ circulating in its sensor unit is caused, and unevenness of temperature (a temperature gradient) is caused in members of the sensor unit, and due to this, it easily causes troubles such as lowering of the accuracy in flow rate control, clogging or condensing of the gas G₀′ flowing in the sensor unit. Problem (B) arises because the apparatus is configured such that the raw material container and the mass flow controller are respectively provided individually. Thus, it is difficult to downsize the raw material vaporizing and supplying apparatus, and the like, and in particular, to provide a raw material vaporizing and supplying apparatus for semiconductor manufacturing equipment which is capable of stably supplying raw material gas generated inside a raw material container to a process chamber while highly accurately performing flow rate control without causing troubles such as clogging of the raw material gas.

### Means for Solving the Problems

In accordance with a first aspect of the invention, a basic configuration of the invention includes a source tank in which a raw material is stored, a raw material gas supply channel through which raw material gas is supplied from an internal space portion of the source tank to a process chamber, a pressure type flow rate control system which is installed along the way of the supply channel, the pressure type flow rate control system operably connected to control a flow rate of the raw material gas which is supplied to the process chamber, and a constant temperature heating unit that heats the source tank, the raw material gas supply channel, and the pressure type flow rate control system to a set temperature, wherein the raw material gas generated in the internal space portion of the source tank is supplied to the process chamber while the pressure type flow rate control system performs flow rate control.

In accordance with a second aspect of the invention, in the invention according to the first aspect, the source tank and the pressure type flow rate control system are integrally assembled fixedly so as to be disengageable.

In accordance with a third aspect of the invention, in the invention according to the first aspect, a branched purge gas supply channel is connected to a primary side of the pressure type flow rate control system, and a branched dilution gas supply channel is connected to a secondary side of the pressure type flow rate control system.

In accordance with a fourth aspect of the invention, in the invention according to the first aspect, a constant temperature heating unit that heats the source tank and a constant temperature heating unit that heats the pressure type flow rate control system and the raw material gas supply channel are separated, to independently temperature-control a heating temperature of the constant temperature heating unit for the source tank and a heating temperature of the constant temperature heating unit for the pressure type flow rate control system and the raw material gas supply channel, respectively.

In accordance with a fifth aspect of the invention, in the invention according to the first aspect, the raw material is trimethylgallium (TMGa) or trimethylindium (TMIn).

In accordance with a sixth aspect of the invention, in the invention according to the first aspect, the raw material is selected from the group consisting of a liquid raw material and a solid raw material is supported by a porous support.

In accordance with a seventh aspect of the invention, in the invention according to the first aspect, the pressure type flow rate control system comprises a control valve CV, a temperature detector T and a pressure detector P which are provided on a downstream side of the control valve CV, an orifice which is provided on a downstream side of the pressure detector P, an arithmetic and control unit is arranged to perform a temperature correction of a flow rate of the raw material gas computed by use of a detection value from the pressure detector P, on the basis of a detection value from the temperature detector T, and compare a predetermined flow rate of the raw material gas and the computed flow rate, so as to output a control signal Pd for controlling opening or closing of the control valve CV in a direction whereby a difference between the computed and predetermined flow rates is reduced, and a heater that heats a flow passage portion through which the raw material gas flows in a body block, to a predetermined temperature.

### Effect of the Invention

The present invention is configured such that the raw material gas inside the source tank is directly supplied to the process chamber while performing flow rate control by the pressure type flow rate control system.

As a result, it is possible to always supply only pure raw material gas toward the process chamber, and it is possible to highly accurately and easily control a concentration of raw material gas in process gas as compared with a conventional raw material vaporizing and supplying apparatus using a bubbling method or a vaporizing method, which makes it possible to manufacture high quality semiconductor products.

Further, because the pressure type flow rate control system is used, troubles are hardly ever caused due to clogging or the like by raw material gas condensation as in a mass flow controller (thermal type mass flow rate control system), which makes it possible to stably supply raw material gas as compared with a conventional raw material vaporizing and supplying apparatus using a thermal type mass flow rate control system.

Moreover, because the pressure type flow rate control system has the characteristics of being less likely to be affected by a pressure fluctuation in the primary side supply source, even when the raw material gas pressure in the source tank slightly fluctuates, it is possible to perform highly accurate flow rate control.

In addition, the source tank and the pressure type flow rate control system are integrally assembled fixedly so as to be disengageable, thereby it is possible to significantly downsize the raw material vaporizing and supplying apparatus, and lower the manufacturing cost.

### BRIEF DESCRIPTION OF THE DRAWINGS

FIG. 1 is a systematic diagram of a configuration of a raw material vaporizing and supplying apparatus according to an embodiment of the present invention.

FIG. 2 is an explanatory diagram of a pressure type flow rate control system.

FIG. 3 is a cross-sectional schematic diagram according to an example of the raw material vaporizing and supplying apparatus according to an embodiment of the present invention.

FIG. 4 is a systematic diagram of a raw material vaporizing and supplying apparatus according to an Example 1 of the present invention.

FIG. 5 shows the result of a flow rate control characteristic test of Example 1, and shows temperatures, detection pressures, set flow rates, flow rate outputs, measurement flow rate values, and the like in the case where the pressure type flow rate control system is an F88A model, and the set pressure P₂′ of a vacuum gauge is 1.0 Torr.

FIG. 6 shows respective measurement values in the same way as in FIG. 5 when the set pressure P₂′ of the vacuum gauge is 5 Torr.

FIG. 7 shows respective measurement values in the same way as in FIG. 5 when the set pressure P₂′ of the vacuum gauge is 10 Torr.

FIG. 8 shows respective measurement values in the same way as in FIG. 5 when the set pressure P₂′ of the vacuum gauge is 0.4 Torr.

FIG. 9 shows the relationship between absorbance of an FT-IR and set flow rate switching time in the test of FIG. 5.

FIG. 10 shows the relationship between absorbance of the FT-IR and set flow rate switching time in the test of FIG. 6.

FIG. 11 shows the relationship between absorbance of the FT-IR and set flow rate switching time in the test of FIG. 7.

FIG. 12 shows the relationship between flow rate set value of the pressure type flow rate control system and absorbance in the test of FIG. 8.

FIG. 13 shows the relationship between flow rate set value of the pressure type flow rate control system and absorbance in the test of FIG. 6.

FIG. 14 shows the relationship between flow rate set value of the pressure type flow rate control system and absorbance in the test of FIG. 7.

FIG. 15 is a systematic diagram of a conventional raw material vaporizing and supplying apparatus using a thermal type mass flow rate control system.

FIG. 16 is an explanatory diagram of a configuration of the thermal type mass flow rate control system.

FIG. 17 is an explanatory diagram for an operation of a sensor unit of the thermal type mass flow rate control system.

### DETAILED DESCRIPTION OF THE PREFERRED EMBODIMENTS

Hereinafter, an embodiment of the present invention will be described with reference to the drawings.

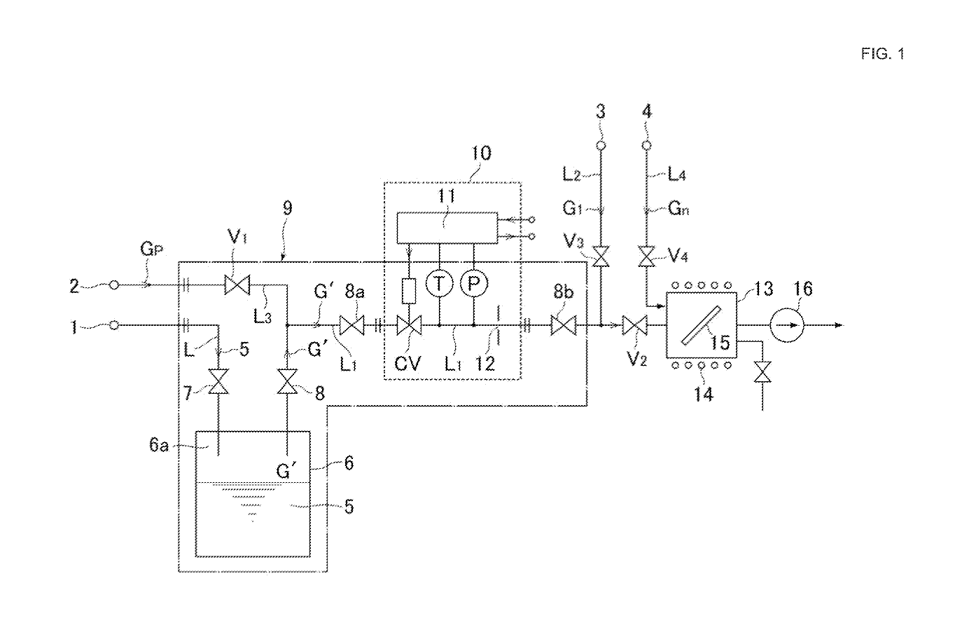

FIG. 1 is a systematic diagram of a configuration of a raw material vaporizing and supplying apparatus according to an embodiment of the present invention. The raw material vaporizing and supplying apparatus is composed of a source tank 6 in which a raw material 5 is stored, a constant temperature heating unit 9 that heats the source tank 6 and the like, and a pressure type flow rate control system 10 which regulates a flow rate of raw material gas G′ which is supplied from an internal upper space 6a of the source tank to a process chamber 13.

In addition, in FIG. 1, reference numeral 1 denotes a raw material supply port, reference numeral 2 denotes a purge gas supply port, reference numeral 3 denotes a dilution gas supply port, reference numeral 4 denotes a different thin film forming gas supply port, reference numeral 7 denotes a raw material inlet valve, reference numerals 8 and 8b denote raw material gas outlet valves, reference numeral 8a denotes a raw material gas inlet valve, reference numeral 14 denotes a heater, reference numeral 15 denotes a substrate, reference numeral 16 denotes a vacuum exhaust pump, reference numerals V₁ to V₄ denote valves, reference numeral L denotes a raw material supply channel, reference numeral L₁ denotes a raw material gas supply channel, and reference numerals L₂ to L₄ denote gas supply channels.

The source tank 6 is formed of stainless steel or the like, and a metal-organic material such as TMGa (trimethylgallium) or TMIn (trimethylindium) is stored inside the source thank 6.

In addition, in the present embodiment, the apparatus is configured to supply the liquid raw material 5 from the raw material supply port 1 through a supply channel L to the inside of the source tank 6. Meanwhile, the apparatus may be configured such that a cassette type tank is used as the source tank 6, and as will be described later, the cassette type source tank 6 which is filled in advance with a high-risk metal-organic material is fixed to a body block (a base body, which is not shown) of the raw material vaporizing and supplying apparatus so as to be detachable, or the source tank 6 and the pressure type flow rate control system 10 are integrally fixed so as to be disengageable. Further, the metal-organic material serving as the raw material 5 may be a liquid material, a particulate material, or a granulate material.

The constant temperature heating unit 9 is to heat the source tank 6 and the pressure type flow rate control system 10 to a set temperature of 40° C. to 120° C. and to keep at that temperature, and is formed from the heater, a heat insulating material, a temperature control unit, and the like. In the present embodiment, the source tank 6 and the pressure type flow rate control system 10 are integrally heated by the single constant temperature heating unit 9. Meanwhile, the constant temperature heating unit may be divided, so as to be capable of individually regulating heating temperatures for the source tank 6 and the pressure type flow rate control system 10.

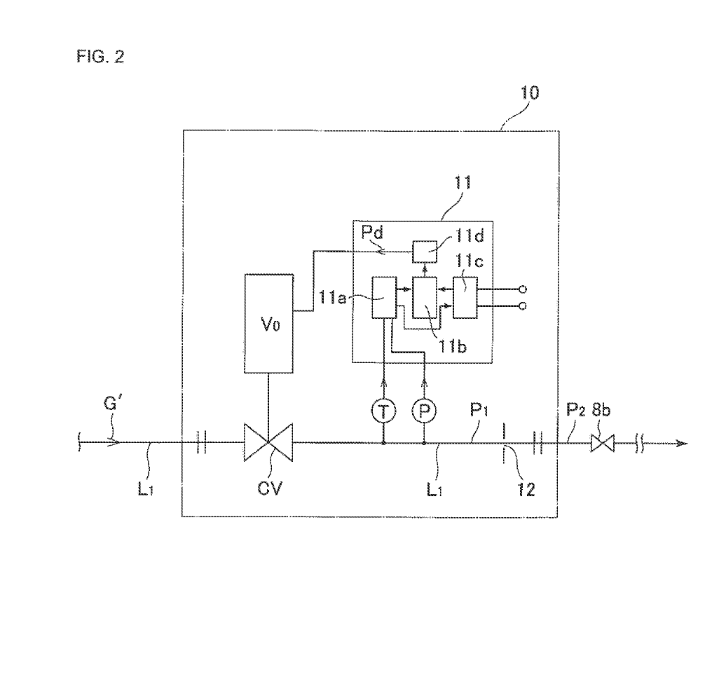

The pressure type flow rate control system 10 is provided to the raw material gas supply channel L₁ on the downstream side of the source tank 6, and as shown in the configuration diagram of FIG. 2, the raw material gas G′ flowing through the control valve CV is made to flow out through an orifice 12. In addition, because the pressure type flow rate control system itself is well-known, the detailed description thereof will be omitted here.

In an arithmetic and control unit 11 of the pressure type flow rate control system 10, a flow rate Q is computed as Q=KP₁ (where K is a constant determined by the orifice) by use of a pressure detection value P in an arithmetic/correction circuit 11a, and the so-called temperature correction of the computed flow rate is performed with a detection value from the temperature detector T, and the temperature-corrected flow rate computed value and the set flow rate value are compared in a comparison circuit 11b, and a difference signal Pd between the both values is output to a drive circuit of the control valve CV. In addition, reference numeral 11c denotes an input/output circuit, and reference numeral 11d denotes a control output amplifier circuit.

The pressure type flow rate control system 10 is well-known as described above. Meanwhile, the pressure type flow rate control system 10 is excellently characterized by that, in the case where the relationship that P₁/P₂ is greater than or equal to about 2 (so-called critical conditions) is maintained between the downstream side pressure P₂ of the orifice 12 (i.e., the pressure P₂ on the side of the process chamber) and the upstream side pressure P₁ of the orifice 12 (i.e., the pressure P₁ on the outlet side of the control valve CV), the flow rate Q of the raw material gas G′ flowing through the orifice 12 becomes Q=KP₁, and it is possible to highly accurately control the flow rate Q by controlling the pressure P₁, and the flow rate control characteristics hardly change even when the raw material gas pressure on the upstream side of the control valve CV is significantly changed.

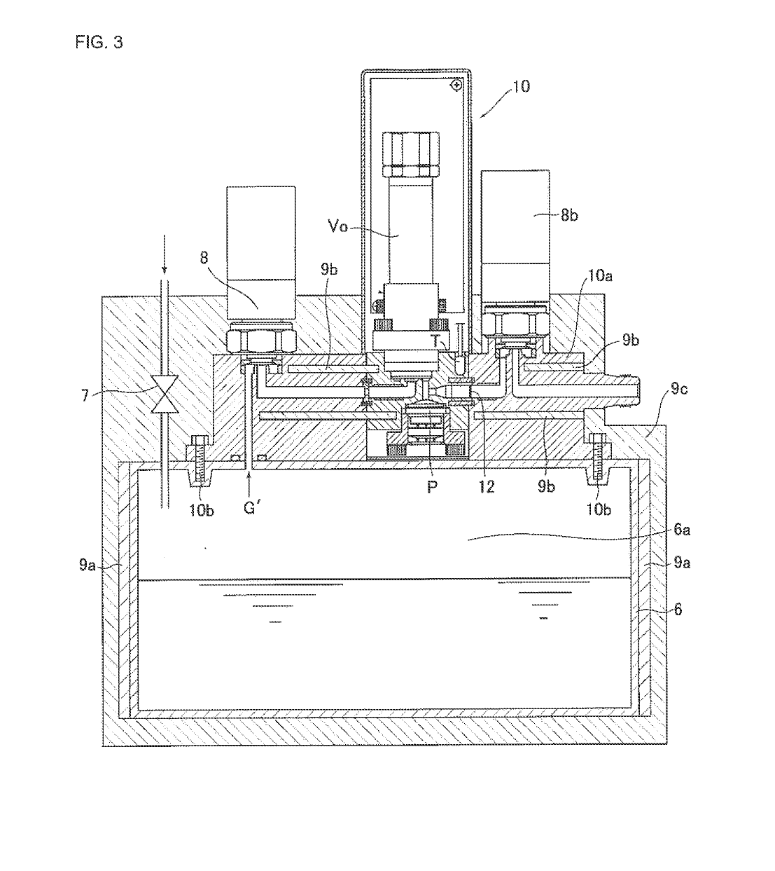

The pressure type flow rate control system 10 is, as shown in FIG. 3, integrally assembled with the upper wall of the source tank 6 so as to be disengageable, and is fixed to the source tank 6 with mounting bolts 10b which are inserted through a body block 10a of the pressure type flow rate control system 10.

In addition, in FIG. 3, reference symbol Vo denotes a drive unit (piezo element) of the control valve CV, and reference numerals 9a and 9b denote heaters of the constant temperature heating unit 9, and reference numeral 9c denotes a heat insulating material of the constant temperature heating unit 9.

With reference to FIG. 1, the inside of the source tank 6 is filled with an appropriate quantity of a liquid material (for example, a metal-organic compound or the like such as TMGa) or a solid raw material (for example, a granulate material of TMIn or a solid raw material in which a metal-organic compound is supported by a porous support), which is heated to 40° C. to 120° C. by a heater (not shown) inside the constant temperature heating unit 9, thereby generating raw material gas G′ at a saturated gas pressure of the raw material 5 at that heated temperature, and the inside of the internal upper space 6a of the source tank 6 is filled with the raw material gas G′.

The generated raw material gas G′ of the raw material 5 flows through the raw material gas outlet valve 8 into the control valve CV of the pressure type flow rate control system 10, and as will be described later, the raw material gas G′ controlled at a predetermined flow rate by the pressure type flow rate control system 10 is supplied to the process chamber 13. Thereby, a required thin film is formed on the substrate 15.

In addition, purge of the supply channel L₁ for the raw material gas G′, etc., is performed by supplying an inactive gas Gp such as N₂ from the purge gas supply port 2, and further, a dilution gas G₁ such as argon or hydrogen is supplied as needed from the dilution gas supply port 3.

Further, because the supply channel L₁ for the raw material gas G′ is heated to 40° C. to 120° C. by the heater in the constant temperature heating unit 9, there is absolutely no case where the circulating raw material gas G′ is condensed to be again liquefied, which does not cause any clogging or the like of the raw material gas supply channel L₁.

### Example 1

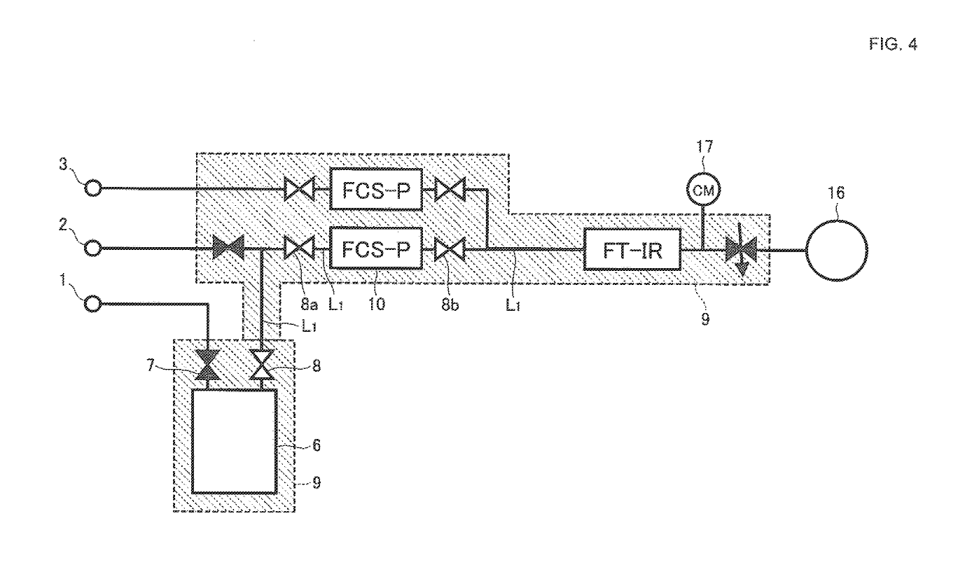

The source tank 6 and the pressure type flow rate control system 10 were installed as shown in FIG. 4, and the flow rate control characteristics of the raw material gas by the pressure type flow rate control system 10 were tested.

First, a cylindrical tank (internal capacity of 100 ml) made of stainless steel was prepared as the source tank 6, and as the raw material 5, trimethylgallium (TMGa/manufactured by Ube Industries, Ltd.) of 80 ml was made to flow into the tank.

The TMGa raw material 5 is in liquid form at room temperature, and is a pyrophoric material having the physical properties: its melting point/freezing point is −15.8° C., its boiling point is 56.0° C., its gas pressure is 22.9 KPa (20° C.), its specific gravity is 1151 kg/m³ (15° C.), and the like.

Further, as the pressure type flow rate control system 10, the FCSP7002-HT50-F450A model (in the case of TMGa gas flow rate of 21.9 to 109.3 sccm) and the F88A model (in the case of TMGa gas flow rate of 4.3 to 21.4 sccm) which are manufactured by Fujikin Incorporated were used.

Moreover, the component identification of TMGa gas on the downstream side of the pressure type flow rate control system 10 was carried out by use of the FTS-50A manufactured by BIO-RAD Inc. as an FT-IR (Fourier Transform Infrared Spectrophotometer).

Table 1 shows the main specifications of the FCSP7002-HT50-F88A model pressure type flow rate control system used for the present example.

TABLE 1
Pressure type flow rate control system (F88A model)

| | |
|---|---|
| Name | Automatic pressure regulating device |
| Flow rate range (F.S.) | 100 kPa abs. •Flow rate: 88 sccm (standard |
| | cubic centimeters per minute)(N₂) |
| Primary side pressure | Lower than or equal to 500 kPa abs. |
| Withstanding pressure | 0.35 MPaG |
| External leak level | Lower than or equal to 1 × 10⁻¹⁰ Pam³/sec |
| Internal leak level | Lower than or equal to 2 × 10⁻⁵ Pam³/sec |
| | (At supply pressure of 300 kPa abs.) |
| Accuracy assurance | 15° C. to 150° C. |
| temperature range | |
| Available | 0° C. to 160° C. |
| temperature range | |
| Environmental | 15° C. to 50° C. |
| temperature | |
| Gas contact member | SUS316L, Nickel-cobalt alloy (diaphragm), |
| material | hastelloy, C-22 (pressure sensor) |
| Mounting posture | Available in all directions |

When conducting a test, first, the inside of the raw material gas supply channel L₁ is vacuumed by the vacuum exhaust pump 16, and argon gas is thereafter introduced from the purge gas supply port 2, and evacuation of the air is performed by the vacuum exhaust pump 16 at the end.

Next, the source tank 6, the pressure type flow rate control system 10, the raw material gas supply channel L₁, and the like are heated to 45° C. by the constant temperature heating unit 9, to keep that temperature, thereby generating the raw material gas G′ (at gas pressure of 69.5 kPa abs.) in the source tank internal portion 6a. Further, the pressure P₂′ of a vacuum gauge 17 at the terminal end of the raw material gas flow passage on the downstream side of the pressure type flow rate control system is kept at a predetermined set value by the vacuum exhaust pump 16.

Thereafter, the flow rate settings of the pressure type flow rate control system 10 were carried out every 10% over the flow rate range of 10 to 50% of its full scale flow rate (F.S.), and the relationship between the set flow rates and measurement values of the TMGa gas flow rates was checked, and absorbance measurement and spectral analysis of the raw material gas (TMGa gas) were carried out by the FT-IR, thereby confirming (identifying) that the circulating gas flow is TMGa gas.

The check for the flow rate control characteristics was repeatedly carried out by use of the pressure P₂′ of the raw material gas supply channel L₁ as parameters (P₂′=10, 5, and 1 Torr).

In addition, in the test of FIG. 4, the argon gas was supplied from the dilution gas supply port 3 to dilute the raw material gas G′ flowing into the FT-IR. This is because it is not possible to measure absorbance by the sensitivity setting of the FT-IR when only the raw material steam G′ is made to circulate, and therefore, a dilution gas is used, which makes it possible to measure absorbance of the FT-IR.

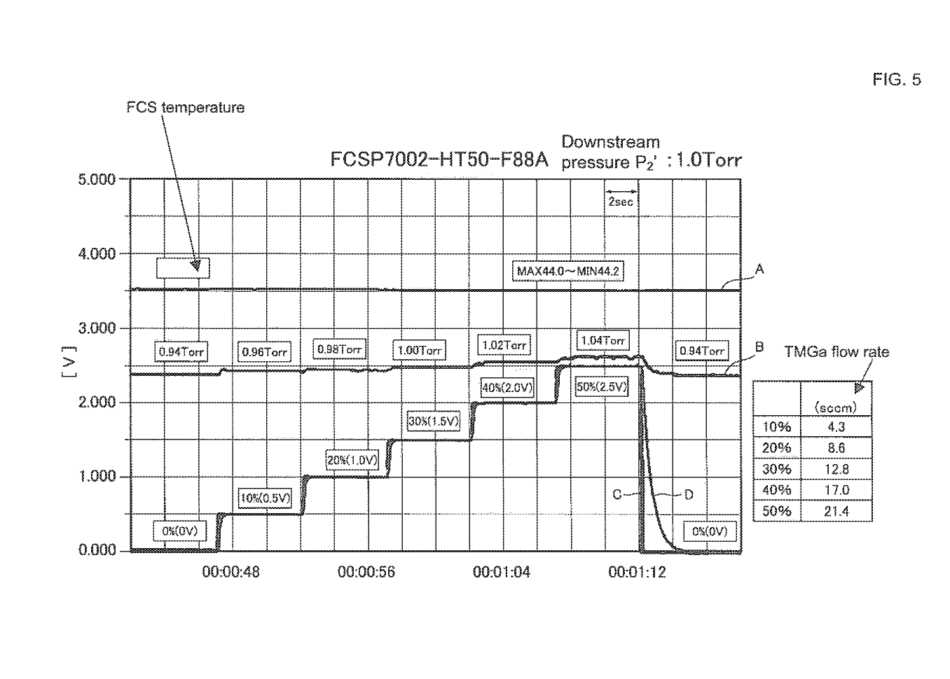

FIG. 5 shows the result of a flow rate control characteristic test of Example 1, and shows the temperatures ° C. (curve A) of the pressure type flow rate control system 10, detection pressures Torr (curve B) of the vacuum gauge 17, set flow rate input signals (curve C) and flow rate output signals (curve D) of the pressure type flow rate control system 10 in the case where the F88A model was used as the pressure type flow rate control system 10, and the set pressure P₂′ of the vacuum gauge 17 on the downstream side thereof is 1.0 Torr, and those were measured by a data logger.

In addition, the temperatures of the pressure type flow rate control system are values measured at a leak port portion on the liquid inlet side (primary side).

Further, the measurement flow rates (sccm) of the TMGa gas flow when the set flow rate signals show the flow rates of 10% to 50% were 4.3 (10%), 8.6 (20%), 12.8 (30%), 17.0 (40%), and 21.4 (50%).

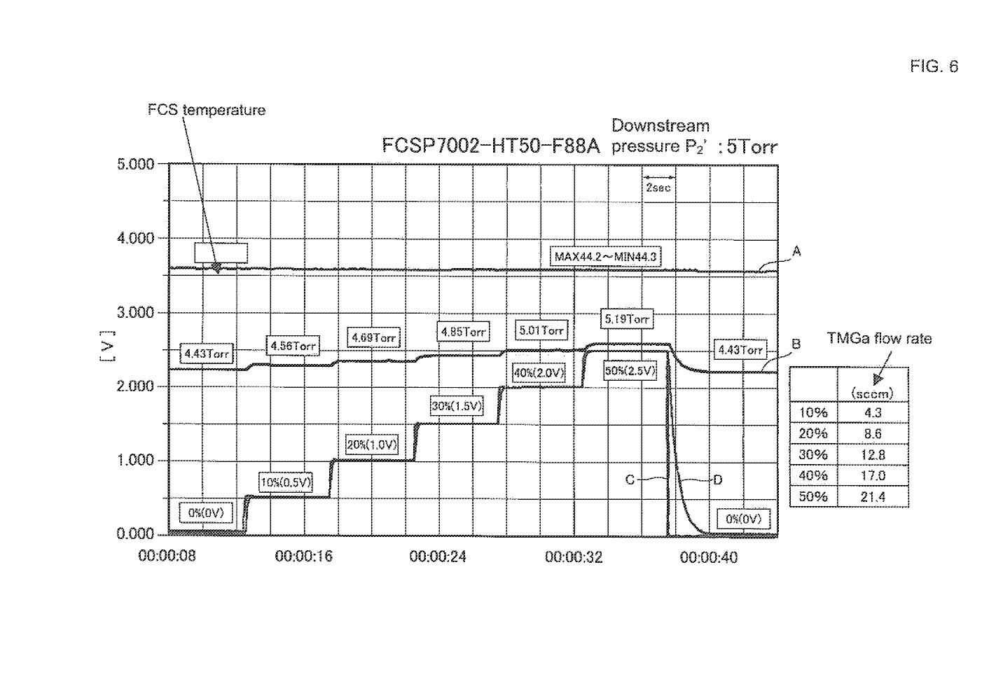

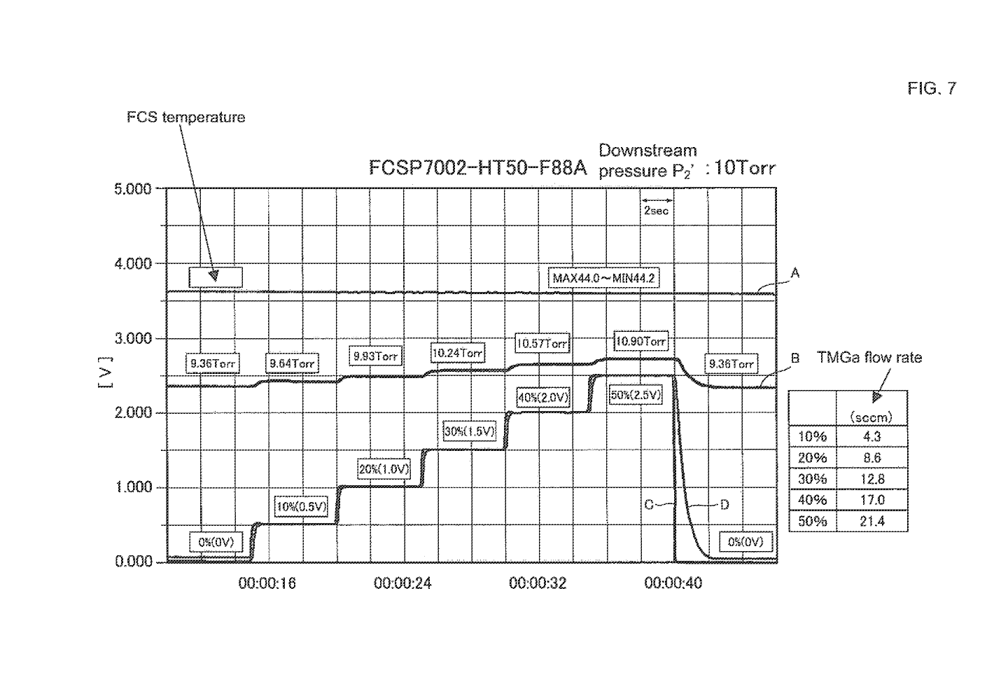

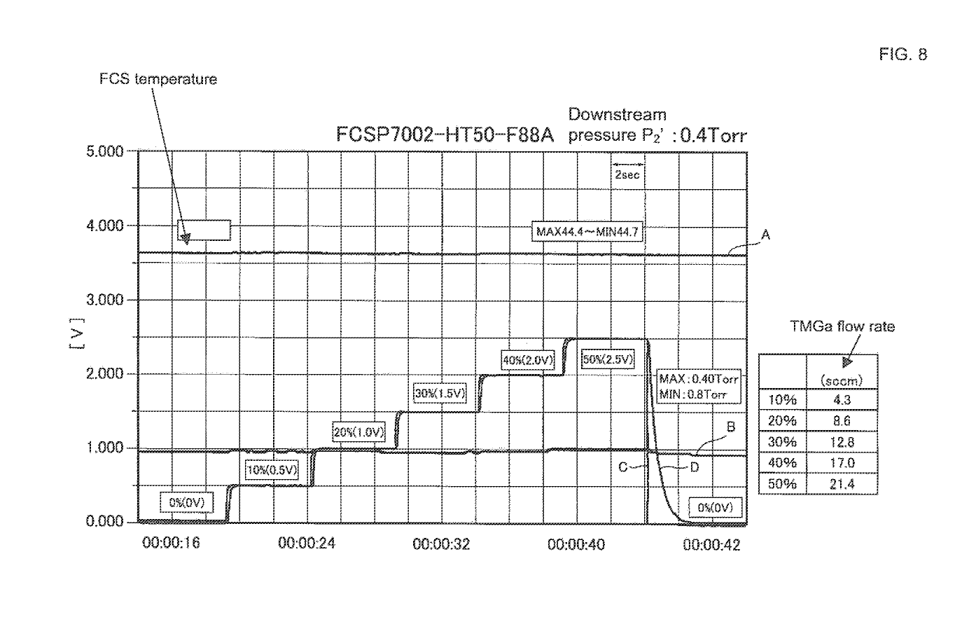

FIG. 6 shows respective characteristic curves in the same way as in FIG. 5 in the case where the pressure type flow rate control system 10 is the F88A, and the set pressure P₂′ of the vacuum gauge 17 is 5 Torr, FIG. 7 shows respective characteristic curves in the same way as in FIG. 5 in the case where P₂′ is 10 Torr, and FIG. 8 shows respective characteristic curves in the same way as in FIG. 5 in the case where P₂′ is 0.4 Torr.

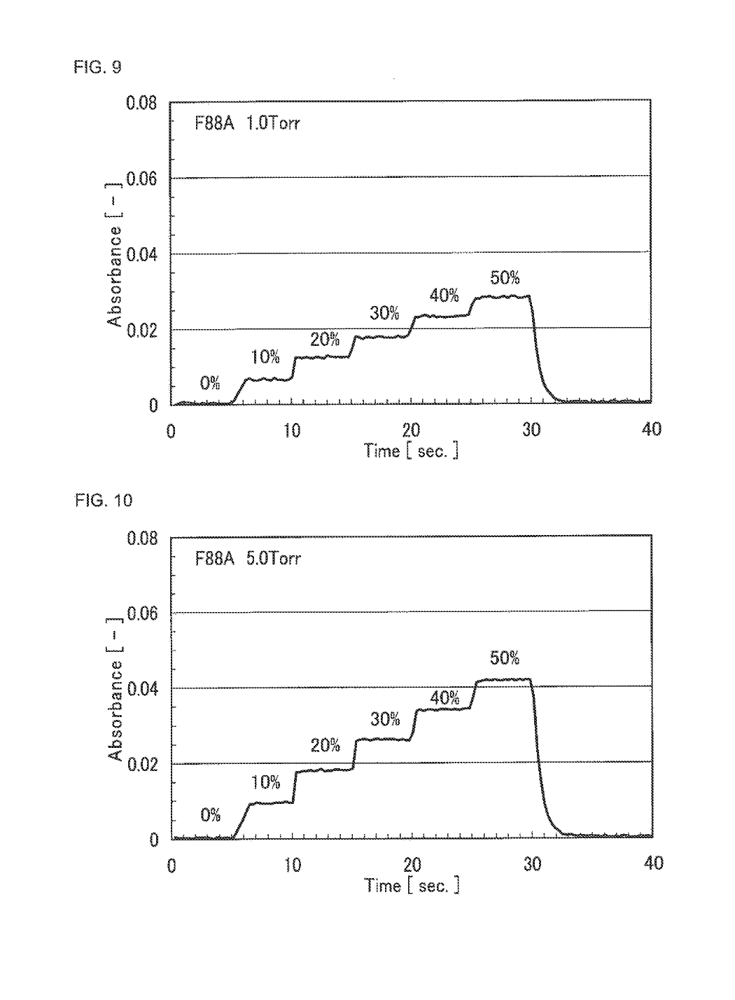

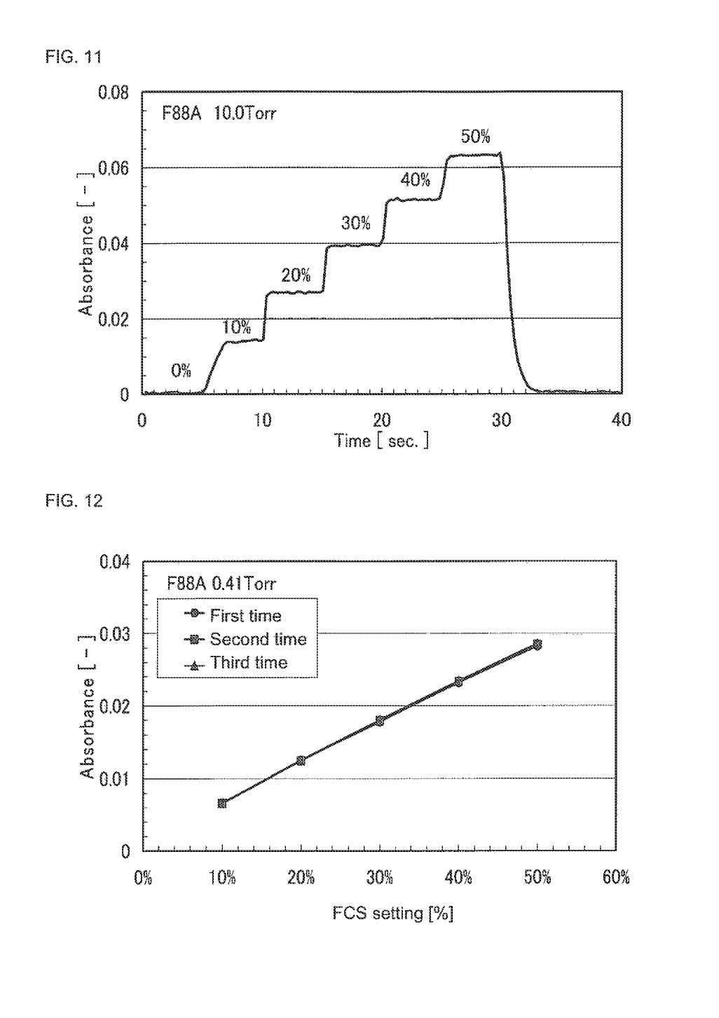

FIG. 9 shows the relationship between absorbance of the FT-IR and set flow rate switching time in the test of FIG. 5 (the pressure type flow rate control system 10 is the F88A model, and the set pressure P₂′ of the vacuum gauge 17 is 10 Torr), and in the same way, FIG. 10 shows the relationship between absorbance and set flow rate switching time in the test of FIG. 6 (the F88A model, and P₂′ is 5.0 Torr), and FIG. 11 shows the relationship between absorbance and set flow rate switching time in the test of FIG. 7.

Further, FIG. 12 shows the relationship between flow rate measurement values % of the pressure type flow rate control system 10 and absorbance in the test of FIG. 8 (the pressure type flow rate control system 10 is the F88A model, and the pressure P₂′ of the vacuum gauge 17 is 0.4 Torr), and the absorbance is an average value of three measurement values.

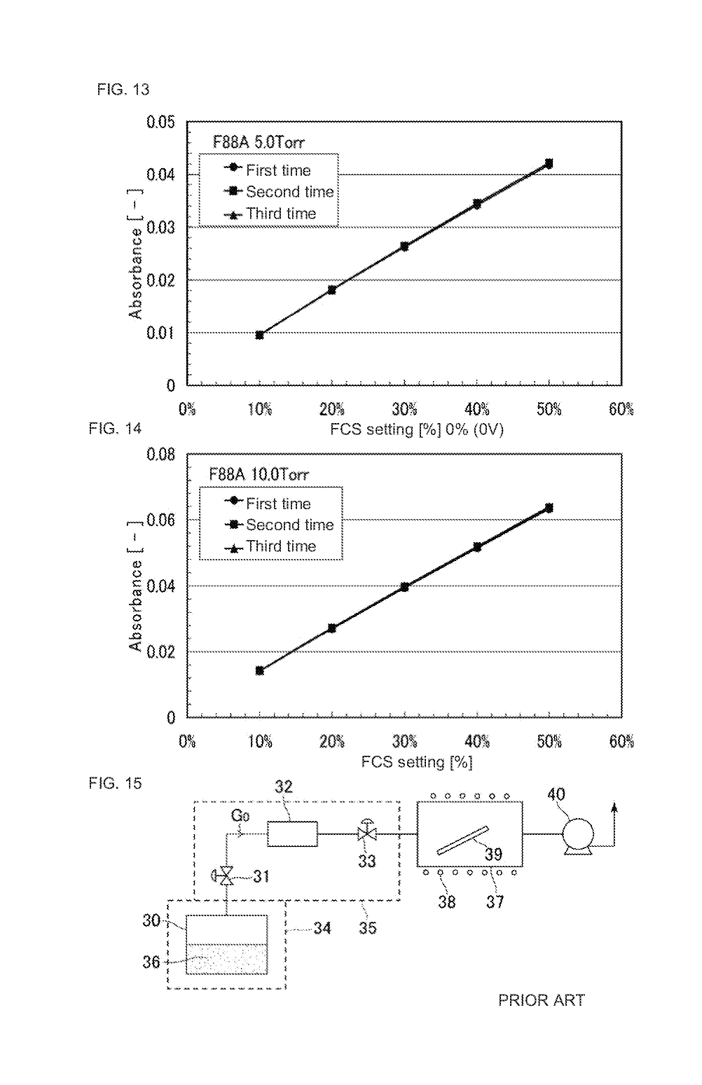

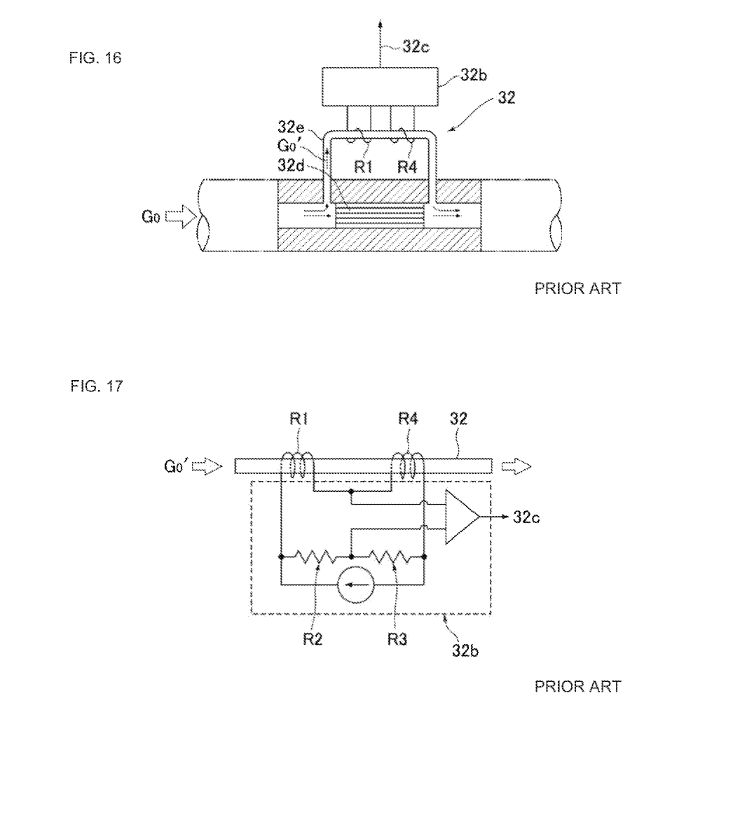

In the same way, respectively, FIG. 13 shows the relationship between set measurement flow rates and absorbance in the test of FIG. 6 (the F88A model, and P₂′ is 5 Torr), and FIG. 14 shows the relationship between set measurement flow rates and absorbance in the test of FIG. 7.

In addition, where the F450A model was used as the pressure type flow rate control system 10 as well, the flow rate control characteristic test which is the same as in the case of the F88A model was carried out, and it has been confirmed that it was possible to stably supply TMGa gas flow at 21.9 sccm (set flow rate of 10%) to 109.3 sccm (set flow rate of 50%).

As is clear from the test results of FIG. 5 to FIG. 8, it has been confirmed that, by heating the source tank 6 and the pressure type flow rate control system 10 to a set temperature by the constant temperature heating unit 9, it was possible to stably supply the TMGa gas to the process chamber while precisely controlling a flow rate to the set flow rate by the pressure type flow rate control system 10 without causing delay in generation of raw material gas (TMGa) and delay in flow rate control.

Further, as is clear from FIG. 9 to FIG. 11 and FIG. 12 to FIG. 14, time delays are hardly observed between a change in a TMGa flow rate and a change in an absorbance measurement value, and extremely high linearity is observed between a TMGa flow rate and absorbance.

From these results, it becomes apparent that the raw material gas G′ inside the source tank 6 is smoothly generated, and it is possible to stably carry out continuous supply of the TMGa gas flow.

### INDUSTRIAL APPLICABILITY

The present invention is widely applicable not only to a raw material vaporizing and supplying apparatus used for the MOCVD method, but also to gas supply apparatuses for supplying a gas flow of a metal-organic material in semiconductor manufacturing equipment, chemical products manufacturing equipment, or the like.

### DESCRIPTION OF REFERENCE SYMBOLS

G′: Raw material gas
V₁ to V₄: Valve
L: Raw material supply channel
L₁: Raw material gas supply channel
L₂ to L₄: Gas supply channel
CV: Control valve
Q: Raw material gas flow rate
P: Pressure detector
T: Temperature detector
Pd: Difference signal
Vo: Drive unit for control valve
1: Raw material supply port
2: Purge gas supply port
3: Dilution gas supply port
4: Different type thin film forming gas supply port
5: Raw material
6: Source tank
6a: Internal space
7: Raw material inlet valve
8, 8b: Raw material gas outlet valve
8a: Raw material gas inlet valve
9: Constant temperature heating unit
9a, 9b: Heater
9c: Heat insulating material
10: Pressure type flow rate control system
10a: Body block
10b: Mounting bolt
11: Arithmetic and control unit
11a: Arithmetic/correction circuit
11b: Comparison circuit
11c: Input/output circuit
11d: Control output circuit
12: Orifice
13: Process chamber
14: Heater
15: Substrate
16: Vacuum exhaust pump
17: Vacuum gauge

1. A raw material vaporizing and supplying apparatus comprising:
a source tank for storing raw material;
a raw material gas supply channel through connected to supply raw material steam gas is supplied-from an internal space portion of the source tank to a process chamber;
a pressure type flow rate control system installed along the way of the supply channel, the pressure type flow rate control system controlling a flow rate of raw material gas supplied to the process chamber; and
a constant temperature heating unit that heats the source tank, the raw material gas supply channel, and the pressure type flow rate control system to a set temperature;
wherein
raw material gas generated in the internal space portion of the source tank is supplied to the process chamber while the pressure type flow rate control system performs flow rate.

2. The raw material vaporizing and supplying apparatus according to claim 1, wherein the source tank and the pressure type flow rate control system are integrally assembled fixedly so as to be disengageable.

3. The raw material vaporizing and supplying apparatus according to claim 1, wherein a branched purge gas supply channel is connected to a primary side of the pressure type flow rate control system, and a branched dilution gas supply channel is connected to a secondary side of the pressure type flow rate control system.

4. The raw material vaporizing and supplying apparatus according to claim 1, wherein a constant temperature heating unit disposed to heat the source tank and a constant temperature heating unit disposed to heat the pressure type flow rate control system and the raw material steam supply channel are provided separately to independently temperature-control a heating temperature of the constant temperature heating unit for the source tank and a heating temperature of the constant temperature heating unit for the pressure type flow rate control system and the raw material steam supply channel, respectively.

5. The raw material vaporizing and supplying apparatus according to claim 1, comprising a raw material selected from the group consisting of the is trimethylgallium (TMGa) or and trimethylindium (TMIn).

6. The raw material vaporizing and supplying apparatus according to claim 1, wherein the raw material is selected from the group consisting of (a) a liquid raw material and (b) a solid raw material supported by a porous support.

7. The raw material vaporizing and supplying apparatus according to claim 1, wherein the pressure type flow rate control system comprises a control valve CV, a temperature detector T and a pressure detector P provided on a downstream side of the control valve CV, an orifice provided on a downstream side of the pressure detector P, an arithmetic and control unit operably connected to perform a temperature correction of a flow rate of the raw material gas computed by use of a detection value from the pressure detector P, on the basis of a detection value from the temperature detector T, and comparing a predetermined flow rate of the raw material gas and a computed flow rate, so as to output a control signal Pd for controlling opening or closing of the control valve CV in a direction whereby a difference between the both flow rates is reduced, and a heater that heats a flow passage portion through which the raw material gas flows in a body block, to a predetermined temperature.
